(19) United States
(12) Patent Application Publication
(10) Pub. No.: US 2026/0251517 A1
(43) Pub. Date: Aug. 27, 2026

(54) PRESSURE SENSOR, METHOD FOR MANUFACTURING THE SAME, AND ELECTRONIC DEVICE

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Weilong GUO, Beijing (CN); Yue LI, Beijing (CN); Taonan ZHANG, Beijing (CN); Qiuxu WEI, Beijing (CN); Lihui WANG, Beijing (CN); Nana HE, Beijing (CN); Jie SUN, Beijing (CN); Wenbo CHANG, Beijing (CN); Yanfei REN, Beijing (CN); Feng QU, Beijing (CN)

(21) Appl. No.: 18/726,775

(22) PCT Filed: Apr. 25, 2023
(86) PCT No.: PCT/CN2023/090503

§ 371 Date: Jul. 3, 2024

(51) Int. Cl. G01L 9/04; B81C 1/00

(52) U.S. Cl. CPC G01L 9/04; B81C 1/00698

(57) ABSTRACT

The present disclosure provides a pressure sensor, including a base substrate (10), and a plurality of sensing units (100) on the base substrate (10). Each of the plurality of sensing units (100) includes a pressure sensing chamber (21), and orthogonal projections of at least two of pressure sensing chambers (21) on the base substrate (10) have areas different from each other. The present disclosure further provides a method for manufacturing a pressure sensor, and an electronic device.

### CROSS-REFERENCE TO RELATED APPLICATIONS

This is a National Phase application filed under 35 U.S.C. 371 as a national stage of PCT/CN2023/090503 filed on Apr. 25, 2023, the entire content of which is incorporated herein by reference.

### TECHNICAL FIELD

The present disclosure relates to the field of sensor technology, and in particular, to a pressure sensor, a method for manufacturing a pressure sensor, and an electronic device.

### BACKGROUND

With the development of semiconductor technology, MEMS (micro-electro-mechanical system) devices (such as pressure sensors, temperature sensors, accelerometers, gyroscopes, image sensors, and photoelectric sensors, which are manufactured by MEMS technology), which are developed based on the semiconductor technology, are widely used in more and more fields such as aerospace, petroleum, chemical engineering, automobiles, consumer electronics, and the like, due to their characteristics of small size, high integration degree, and mass production.

### SUMMARY

To solve at least one of technical problems in the prior art, the present disclosure provides a pressure sensor, a method for manufacturing a pressure sensor, and an electronic device.

Embodiments of the present disclosure provide a pressure sensor, which includes a base substrate, and a plurality of sensing units on the base substrate, wherein each of the plurality of sensing units includes a pressure sensing chamber, and orthogonal projections of at least two of pressure sensing chambers on the base substrate have areas different from each other.

In an embodiment, the pressure sensor further includes a first pressure sensing layer and a second pressure sensing layer, wherein the first pressure sensing layer and the second pressure sensing layer are arranged on two sides of each pressure sensing chamber in a depth direction of the pressure sensing chamber, the first pressure sensing layer includes first pole plates of respective sensing units, and the second pressure sensing layer includes second pole plates of the respective sensing units.

In an embodiment, the base substrate includes a silicon substrate, and the first pole plates are obtained by performing ion implantation on the silicon substrate.

In an embodiment, a material of the second pressure sensing layer is monocrystalline silicon.

In an embodiment, the pressure sensor further includes a first connection component electrically connected to the first pressure sensing layer and a second connection component electrically connected to the second pressure sensing layer.

In an embodiment, the first connection component is located on a side of the first pressure sensing layer proximal to the second pressure sensing layer, and the second connection component is located on a side of the second pressure sensing layer distal to the first pressure sensing layer.

In an embodiment, each pressure sensing chamber is on the base substrate, the pressure sensor further includes a pressure sensing layer on a side of each pressure sensing chamber distal to the base substrate, each sensing unit includes four pressure sensing resistors which are formed on the pressure sensing layer and connected in series, and the four pressure sensing resistors form a Wheatstone bridge.

In an embodiment, the pressure sensing resistors in each sensing unit are obtained by performing ion implantation on the pressure sensing layer.

In an embodiment, each sensing unit further includes conductive wires connecting the pressure sensing resistors together in series, and the conductive wires are located on a side of the pressure sensing layer distal to the base substrate.

In an embodiment, the base substrate is a silicon substrate.

In an embodiment, the plurality of sensing units are arranged in an array, the areas of the orthogonal projections of the pressure sensing chambers of the sensing units in a same row on the base substrate are monotonously increased or monotonously decreased, and/or the areas of the orthogonal projections of the pressure sensing chambers of the sensing units in a same column on the base substrate are monotonously increased or monotonously decreased.

In an embodiment, in a case where the areas of the orthogonal projections of the pressure sensing chambers of the sensing units in a same row on the base substrate are monotonously increased or monotonously decreased, the areas of the orthogonal projections of the pressure sensing chambers of the sensing units in the same row on the base substrate are changed in equal proportions or in equal differences; and in a case where the areas of the orthogonal projections of the pressure sensing chambers of the sensing units in a same column on the base substrate are monotonously increased or monotonously decreased, the areas of the orthogonal projections of the pressure sensing chambers of the sensing units in the same column on the base substrate are changed in equal proportions or in equal differences.

In an embodiment, the orthogonal projection of each pressure sensing chamber on the base substrate has a shape of a rectangle or a circle.

Embodiments of the present disclosure provide a method for manufacturing a pressure sensor, the method including forming a plurality of sensing units on a base substrate, wherein the forming a plurality of sensing units includes forming respective pressure sensing chambers, and orthogonal projections of at least two of the pressure sensing chambers on the base substrate have areas different from each other.

In an embodiment, the forming respective pressure sensing chambers includes forming a support layer on the base substrate, and patterning the support layer to form the respective pressure sensing chambers.

In an embodiment, the method further includes forming a first pressure sensing layer and a second pressure sensing layer on two sides of each pressure sensing chamber in a depth direction of the pressure sensing chamber, wherein the first pressure sensing layer includes first pole plates disposed in one-to-one correspondence with the pressure sensing chambers, and the second pressure sensing layer includes second pole plates disposed in one-to-one correspondence with the pressure sensing chambers.

In an embodiment, the base substrate is a silicon substrate, and the first pressure sensing layer is formed by performing ion implantation on the silicon substrate.

In an embodiment, the forming a second pressure sensing layer on the pressure sensing chambers includes:
providing an SOI sheet, wherein the SOI sheet includes an auxiliary substrate, and a transition layer and a monocrystalline silicon layer which are arranged on the auxiliary substrate;
bonding the monocrystalline silicon layer of the SOI sheet with the base substrate provided with the pressure sensing chambers; and
removing the auxiliary substrate and the transition layer to remain the monocrystalline silicon layer, thereby forming the second pressure sensing layer.

In an embodiment, the method further includes forming a pressure sensing layer on a side of each pressure sensing chamber distal to the base substrate, and performing ion implantation on the pressure sensing layer to form a Wheatstone bridge for each sensing unit, wherein the Wheatstone bridge includes four pressure sensing resistors connected in series.

In an embodiment, the method further includes forming conductive wires on a side of the pressure sensing layer distal to the base substrate, wherein the conductive wires in each sensing unit connect the pressure sensing resistors in the sensing unit in series.

In an embodiment, the plurality of sensing units are arranged in an array, the areas of the orthogonal projections of the pressure sensing chambers of the sensing units in a same row on the base substrate are equal to each other, monotonously increased or monotonously decreased, and/or the areas of the orthogonal projections of the pressure sensing chambers of the sensing units in a same column on the base substrate are monotonously increased or monotonously decreased.

In an embodiment, in a case where the areas of the orthogonal projections of the pressure sensing chambers of the sensing units in a same row on the base substrate are monotonously increased or monotonously decreased, the areas of the orthogonal projections of the pressure sensing chambers of the sensing units in the same row on the base substrate are changed in equal proportions or in equal differences; and in a case where the areas of the orthogonal projections of the pressure sensing chambers of the sensing units in a same column on the base substrate are monotonously increased or monotonously decreased, the areas of the orthogonal projections of the pressure sensing chambers of the sensing units in the same column on the base substrate are changed in equal proportions or in equal differences.

In an embodiment, the orthogonal projection of each pressure sensing chamber on the base substrate has a shape of a rectangle or a circle.

Embodiments of the present disclosure provide an electronic device, which includes the pressure sensor according to any one of foregoing embodiments.

### BRIEF DESCRIPTION OF THE DRAWINGS

FIG. 1 is a top view illustrating a single square film.

FIG. 2 is a top view illustrating a single circular film.

FIG. 3 is a cross-sectional view illustrating a single pressure-sensing film resistive or capacitive pressure sensor.

FIG. 4 is a top view illustrating a pressure sensor including sensing units arranged in an array and having square films with equal areas (i.e., equal-area square films).

FIG. 5 is a top view illustrating a pressure sensor including sensing units arranged in an array and having circular films with equal areas.

FIG. 6 is a graph illustrating an output characteristic curve of a pressure sensor including sensing units arranged in an array and having square films with equal areas;

FIG. 7 is a top view illustrating a capacitive pressure sensor including sensing units arranged in an array and having square films with equally proportionally varying areas (i.e., equally-proportionally-varying-area square films).

FIG. 8 is a top view illustrating a capacitive pressure sensor including sensing units arranged in an array and having circular films with equally proportionally varying areas.

FIG. 9 is a cross-sectional view illustrating a capacitive pressure sensor including sensing units having square films with equally proportionally varying areas.

FIG. 10 is a graph illustrating an output characteristic curve of a capacitive pressure sensor including sensing units arranged in an array and having square films with equally proportionally varying areas.

FIG. 11 is a flowchart illustrating a method for manufacturing a capacitive pressure sensor including sensing units having square films with equally proportionally varying areas.

FIG. 12 is a top view illustrating a piezoresistive pressure sensor including sensing units arranged in an array and having square films with equally proportionally varying areas.

FIG. 13 is a circuit diagram illustrating a Wheatstone bridge.

FIG. 14 is a cross-sectional view illustrating a piezoresistive pressure sensor including sensing units having square films with equally proportionally varying areas.

FIG. 15 is a flowchart illustrating a method for manufacturing a piezoresistive pressure sensor including sensing units having square films with equally proportionally varying areas.

### DETAILED DESCRIPTION OF EMBODIMENTS

To make technical solutions of the present disclosure better understood by one of ordinary skill in the art, the present disclosure will be further described in detail with reference to the accompanying drawings and exemplary embodiments below.

Unless defined otherwise, technical or scientific terms used herein shall have the ordinary meaning as understood by one of ordinary skill in the art to which the present disclosure belongs. The use of “first”, “second”, and the like in the present disclosure is not intended to indicate any order, quantity, or importance, but rather is used to distinguish one element from another. Also, the use of the terms “a”, “an”, “the”, or the like does not denote a limitation of quantity, but rather denotes the presence of at least one. The term of “comprising”, “including”, or the like, means that the element or item preceding the term contains the element or item listed after the term and its equivalent, but does not exclude the presence of other elements or items. The term “connected”, “coupled”, or the like is not limited to physical or mechanical connections, but may include electrical connections, whether direct or indirect. The terms “upper”, “lower”, “left”, “right”, and the like are used only for indicating relative positional relationships, and when the absolute position of an object being described is changed, the relative positional relationships may also be changed accordingly.

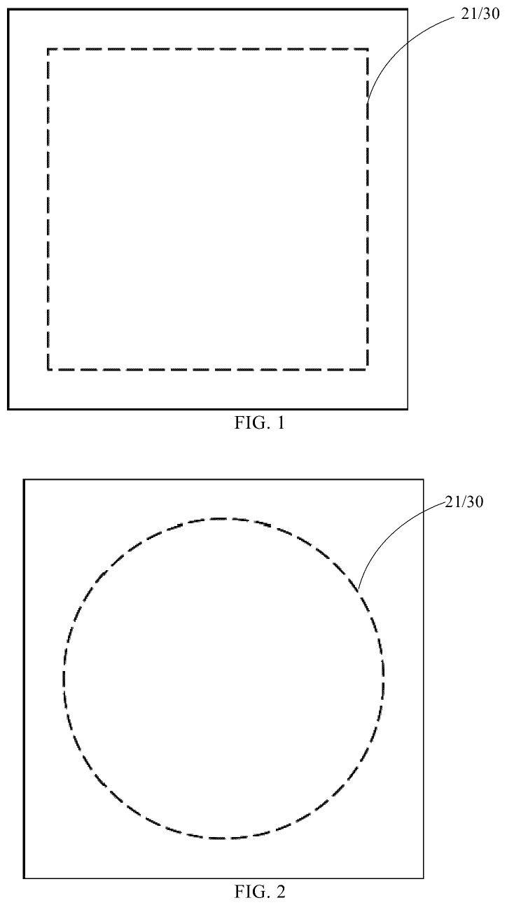

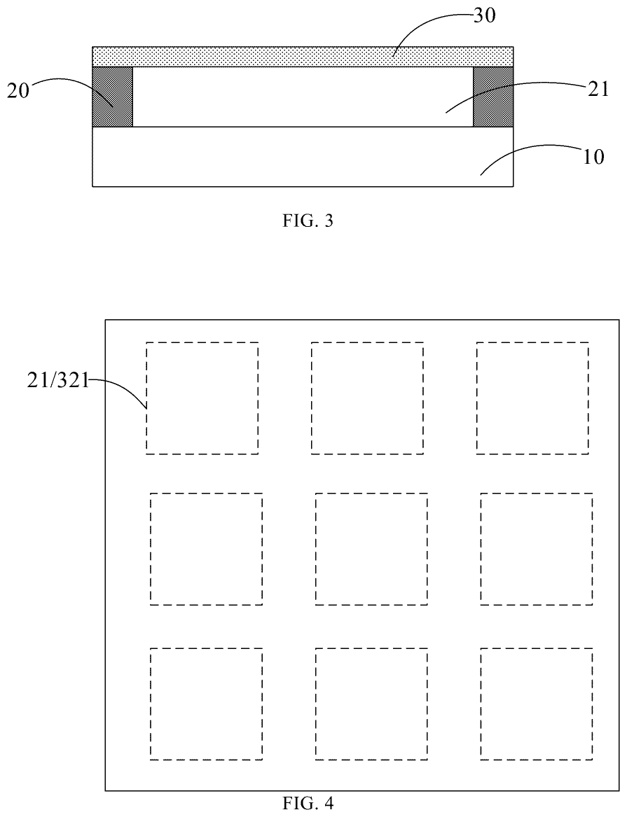

For MEMS pressure sensors, the two most prevailing technical principles are to utilize a piezoresistive effect or a capacitive effect to convert a pressure into a corresponding electrical signal, where in the former one, ions are generally injected into a specific region of a monocrystalline silicon film to realize a silicon resistor strip with a certain doping concentration, and the film is deformed due to a pressure to cause a change of silicon resistance; in the latter one, a capacitor is formed by two parallel and opposite low-resistance films, a pressure causes the films to deform, and a relative distance between the two films changes to cause a change of capacitance. The two technical principles have commonality that a physical structure for sensing a pressure is a film 30. However, it should be understood that each pressure sensor includes a pressure sensing chamber 21 for carrying the film 30 and providing a deformation space for the film 30, the pressure sensing chamber 21 is disposed on a base substrate 10, a support layer 20 is disposed on the base substrate 10, and the pressure sensing chamber 21 is formed in the support layer 20. A shape of the film is generally a circle as shown in FIG. 1 or a square as shown in FIG. 2, and a cross-sectional view of each pressure sensor is shown in FIG. 3. The shape of the film 30 is identical to an outline of an orthogonal projection of the pressure sensing chamber 21 on the base substrate 10.

In designing a pressure sensor with a film as a sensitive element, two main principles are usually to be met, which are when the pressure sensor is at its full measuring range, 1) the maximum deflection thereof is not more than 20% of the film, and 2) the maximum stress thereof is not more than 20% of an allowable stress.

In the case of a circular film.

$${ω}_{max} = \frac{3 p ( 1 - {v}^{2} ) {R}^{4}}{16 {Eh}^{3}} \leq 20 \% h \qquad ( 1 )$$

$${σ}_{max} = \frac{3 {pR}^{2}}{4 {h}^{2}} \leq 20 \% {σ}_{l} \qquad ( 2 )$$

In the case of a square film,

$${ω}_{max} = 0.01518 \frac{{pl}^{4} ( 1 - {v}^{2} )}{{Eh}^{3}} \leq 20 \% h \qquad ( 3 )$$

$${σ}_{max} = 0.308 \frac{{pl}^{2}}{{h}^{2}} \leq 20 \% {σ}_{l} \qquad ( 4 )$$

After a material of the film is selected, the Young's modulus E, the Poisson's ratio v, and the allowable stress or are all constant values (i.e., fixed values), and the deflection is only dependent on an applied pressure p, a radius R or a length l of a side, and a thickness h. Generally, for a single deformable film, the radius (or the length of a side) is limited by application requirements and directly determines a size of a sensitive device; (1) in a case where a small pressure is to be measured, if the thickness remains constant, although the above formulas can be met, a sensitivity of the sensor will be greatly decreased, leading to an increase in amplification during signal processing; further, it is inevitable to amplify noise signals, which has a significant impact on an accuracy of the sensor; in other words, the measuring range of the sensor is limited to a certain range; (2) the thickness is decreased synchronously and meets the above formulas, which will increase the difficulty of a manufacturing process, and an inevitable deviation in thickness will lead to poor product consistency; (3) in order to simultaneously meet the requirements of measuring the pressure p and the thickness h, considering the feasibility of a process, it is often required to increase the radius R or the length l of a side of the film, making the product have a large size and not meet some application scenarios; and (4) in addition, the nonlinearity of deformation of a single film is often relatively large, which requires signal fitting to use multiple data points and a complex multi-order fitting formula.

In view of an existing pressure sensor having any one of the above problems, embodiments of the present disclosure provide the following technical solutions. A pressure sensor according to an embodiment of the present disclosure may be a capacitive pressure sensor or a piezoresistive pressure sensor. Hereinafter, the pressure sensor according to an embodiment of the present disclosure will be described by taking the pressure sensor as the capacitive pressure sensor and the piezoresistive pressure sensor as examples.

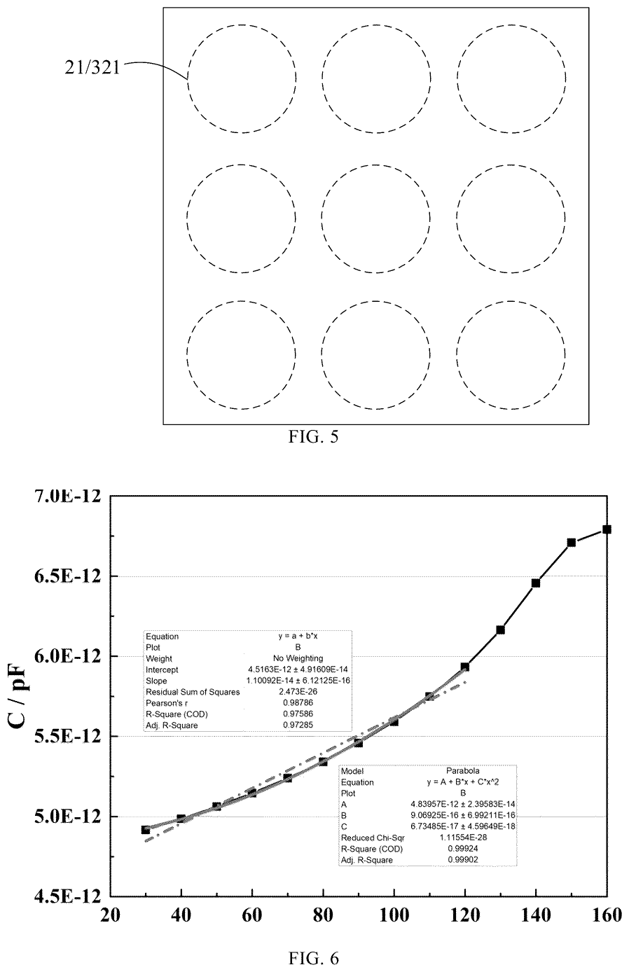

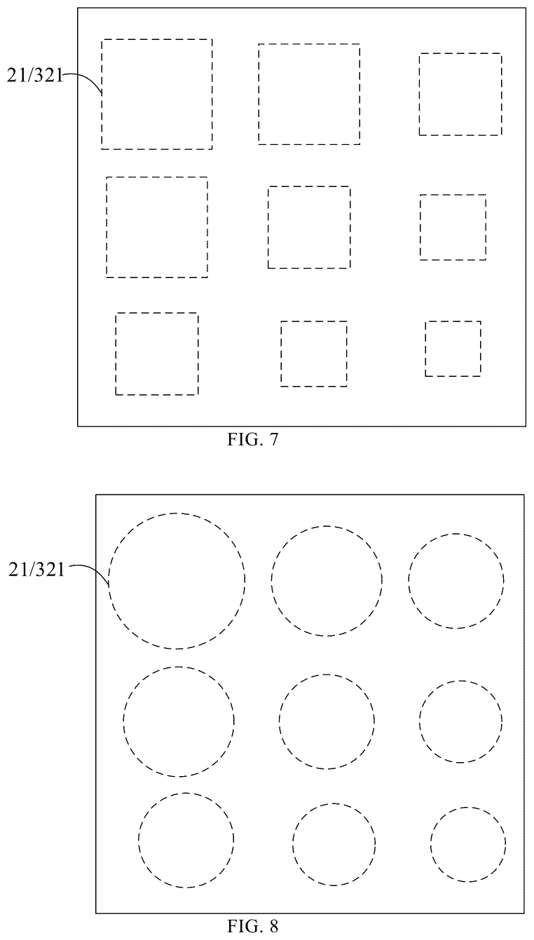

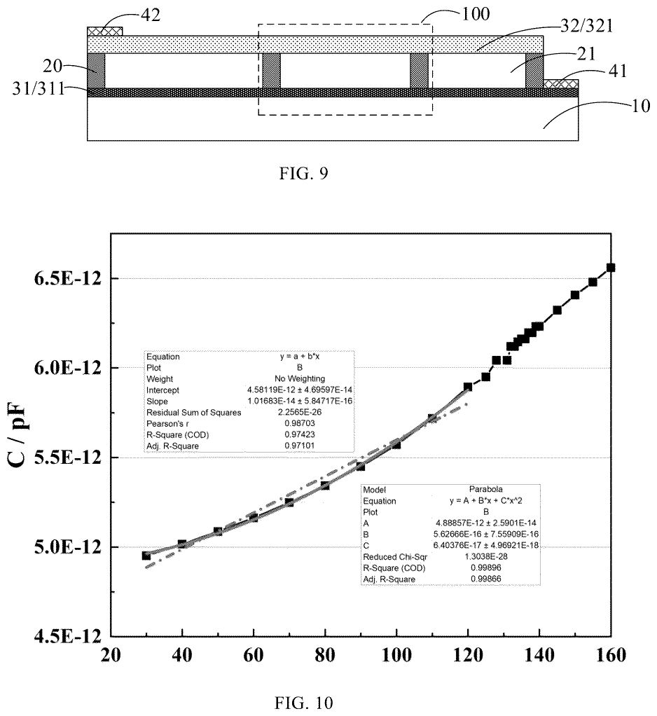

In a first example, FIG. 4 is a top view illustrating a pressure sensor including sensing units 100 arranged in an array and having square films with equal areas, FIG. 5 is a top view illustrating a pressure sensor including sensing units 100 arranged in an array and having circular films with equal areas, FIG. 7 is a top view illustrating a capacitive pressure sensor including sensing units 100 arranged in an array and having square films with equally proportionally varying areas, FIG. 8 is a top view illustrating a capacitive pressure sensor including sensing units 100 arranged in an array and having circular films with equally proportionally varying areas, and FIG. 9 is a cross-sectional view illustrating a capacitive pressure sensor including sensing units 100 having square films with equally proportionally varying areas. As shown in FIGS. 4 to 5 and 7 to 9, the pressure sensor is a capacitive pressure sensor, and includes a base substrate 10, and a first pressure sensing layer 31, a support layer 20, and a second pressure sensing layer 32 which are formed on the base substrate 10. Only the second pressure sensing layer in the first pressure sensing layer 31 and the second pressure sensing layer 32 is deformable under a pressure. The support layer 20 has a plurality of pressure sensing chambers 21 formed therein. The first pressure sensing layer 31 includes a plurality of first pole plates 311, and the second pressure sensing layer 32 includes a plurality of second pole plates 321. Both the first pole plates 311 and the second pole plates 321 are disposed corresponding to the respective pressure sensing chambers 21, i.e., one first pole plate 311 and one second pole plate 321 are disposed on two sides of one pressure sensing chamber 21 along a depth direction of the one pressure sensing chamber 21. As such, the one first pole plate 311, the one second pole plate 321, and the pressure sensing chamber 21 between the one first pole plate 311 and the one second pole plate 321 form a sensing unit 100. By dividing one pressure sensing chamber 21 included in the pressure sensor into a plurality of pressure sensing chambers 21 included in the pressure sensors, the second pressure sensing layer 32 can be formed to be relatively thin, such that the maximum deflection and the maximum stress of the film satisfy the formulas (3) and (4) while ensuring the sensitivity; if the thickness of the second pressure sensing layer 32 is not changed, the pressure sensor including the plurality of pressure sensing chambers 21 can measure a larger pressure than the pressure sensor including the single pressure sensing chamber 21 on the premise of satisfying the formulas.

In some examples, orthogonal projections of the pressure sensing chambers 21 of at least two of the plurality of sensing units 100 of the pressure sensor on the base substrate 10 have different areas. It should be noted that the area of the orthogonal projection of a pressure sensing chamber 21 on the base substrate 10 determines an area of the first pole plate 311 and an area of the second pole plate 321 in a sensing unit 100. Since the first pole plate 311 and the second pole plate 321 of each sensing unit 100 are respectively disposed on two sides of the depth direction of the corresponding pressure sensing chamber 21, the area of the orthogonal projection of the pressure sensing chamber 21 on the base substrate 10 being larger will result in that the area of the first pole plate 311 and/or the area of the second pole plate 321 of the sensing unit 100 are larger, and vice versa. That is, in an embodiment of the present disclosure, the areas of the orthogonal projections of at least two pressure sensing chambers 21 on the base substrate 10 are different, i.e., the areas of the first pole plate 311 and/or the second pole plate 321 of at least two sensing units 100 are different. The first pole plate 311 and the second pole plate 321 of each sensing unit 100 are both pressure sensing layers. Hereinafter, areas of the pressure sensing layers of at least two sensing units 100 being different means that the areas of the first pole plate 311 and/or the second pole plate 321 of the at least two sensing units 100 are different.

In an example, the sensing units 100 are arranged in an array; the areas of the orthogonal projections of the pressure sensing chambers 21 of the sensing units 100 in a same row on the base substrate 10 are monotonously increased or monotonously decreased, and/or the areas of the orthogonal projections of the pressure sensing chambers 21 of the sensing units 100 in a same column on the base substrate 10 are monotonously increased or monotonously decreased.

For example, in the case where the areas of the orthogonal projections of the pressure sensing chambers 21 of the sensing units 100 in a same row on the base substrate 10 are monotonously increased or monotonously decreased, the areas of the orthogonal projections of the pressure sensing chambers 21 of the sensing units 100 in the same row on the base substrate 10 are changed in equal proportions or in equal differences. In the case where the areas of the orthogonal projections of the pressure sensing chambers 21 of the sensing units 100 in a same column on the base substrate 10 are monotonously increased or monotonously decreased, the areas of the orthogonal projections of the pressure sensing chambers 21 of the sensing units 100 in the same column on the base substrate 10 are changed in equal proportions or in equal differences.

Specifically, referring to FIG. 7, the pressure sensor includes 9 sensing units 100 in total in an array of 3×3. The orthogonal projection of each of the pressure sensing chambers 21 on the base substrate 10 is a square, the areas of the orthogonal projections of the pressure sensing layers in a same row on the base substrate 10 are decreased in equal proportions, and the areas of the orthogonal projections of the pressure sensing layers in a same column on the base substrate 10 are decreased in equal proportions. Taking a difference of 2% between the areas of the orthogonal projections of any adjacent two pressure sensing layers on the base substrate 10 as an example, the maximum area of a single pressure sensing layer may be 0.04 mm², and the minimum area of a single pressure sensing layer may be 0.04×(0.98)⁴ mm². The linearity of the pressure sensing layers of the sensing units 100 in a same column in this pressure sensor is significantly improved (with a decrease of 70% in nonlinearity) compared to a traditional single film or a group of equal-area films. The deviation of the films introduced during processing is equivalent to an influence on one or several pressure sensing layers, rather than on the overall pressure sensor, thereby ensuring good process consistency. For example, if a thickness of the processed film is 1.3% larger than a design value, it can be inferred that

$${ω}_{max} ∝ p \frac{{s}^{2}}{{h}^{3}}$$

according to formulas (1) and (3). When an area and an input pressure remain constant, a ratio of the deflection of the processed film to a design value is 1:1.04, which is exactly the ratio of the squares of the areas of the pressure sensing layers of any adjacent two sensing units 100. For a capacitive pressure sensor including flat plates having a variable distance therebetween, when two pole plates come into contact with each other, a sudden change in capacitance is often caused, resulting in a significant inflection point deviation in the overall output, which limits the measuring range thereof. The output characteristic curve illustrating that a capacitance value is changed with air pressure in this embodiment of the capacitive pressure sensor is shown in FIG. 10. It can be seen that the capacitance no longer includes the inflection point of the output characteristic curve of the pressure sensor of FIG. 4 as shown in FIG. 6, thereby greatly improving the measurement accuracy of the sensor. Investigating the capacitance output values in the air pressure range of 30 kPa to 120 kPa, the nonlinearity of the capacitance is about 1.5%, which is only 30% of the previous embodiment, greatly reducing the nonlinearity and compensation difficulty of the sensor.

The above is only an exemplary structure of the pressure sensor, and it is alternatively possible to have the pressure sensing layers of the sensing units 100 in a same column vary in equal differences. For example, the areas of the pressure sensing layers of the sensing units 100 may be decreased from top to bottom, and a difference between any adjacent two of the pressure sensing layers is constant. Alternatively, for example, the areas of the pressure sensing layers of the sensing units 100 may be increased from top to bottom, and a difference between any adjacent two of the pressure sensing layers is constant. With such configurations, the same effect that the pressure sensing layers of the sensing units 100 in a same column are changed in equal proportions can also be achieved, and therefore, the detailed description thereof is omitted here.

In some examples, a shape of the orthogonal projection of the pressure sensing chamber 21 of each sensing unit 100 on the base substrate 10 is not limited to a square as described above, and may be a circle.

In some examples, the base substrate 10 is made of a silicon substrate, and the first pole plate 311 of each sensing unit 100 is obtained by performing ion implantation on the silicon substrate, i.e., the first pole plates 311 of the sensing units 100 can be obtained by processing the silicon substrate, thereby making the sensor light and thin.

The silicon substrate may be a P-type silicon substrate, and in this case phosphorus ions may be implanted into the P-type silicon substrate, an N well may be formed by high-temperature annealing, boron ions may be implanted into a surface of the P-type silicon substrate with high-concentration ion column, and a P+ layer may be formed by rapid thermal annealing, thereby forming the first pole plates 311 of the sensing units 100. The silicon substrate may be an N-type silicon substrate, and in this case boron ions may be implanted into the N-type silicon substrate, a P well may be formed by high-temperature annealing, phosphorus ions may be implanted into a surface of the N-type silicon substrate with high-concentration ion column, and an N+ layer may be formed by rapid thermal annealing, thereby forming the first pole plates 311 of the sensing units 100.

In some embodiments, a material of the support layer 20 of the pressure sensor may be silicon oxide.

To make the structure of the capacitive pressure sensor clearer, the capacitive pressure sensor is further described below in conjunction with a method for manufacturing the capacitive pressure sensor. The following description will be given by taking an example in which the base substrate 10 is made of a silicon substrate, and the first pole plates 311 of the sensing units 100 are obtained by processing the silicon substrate.

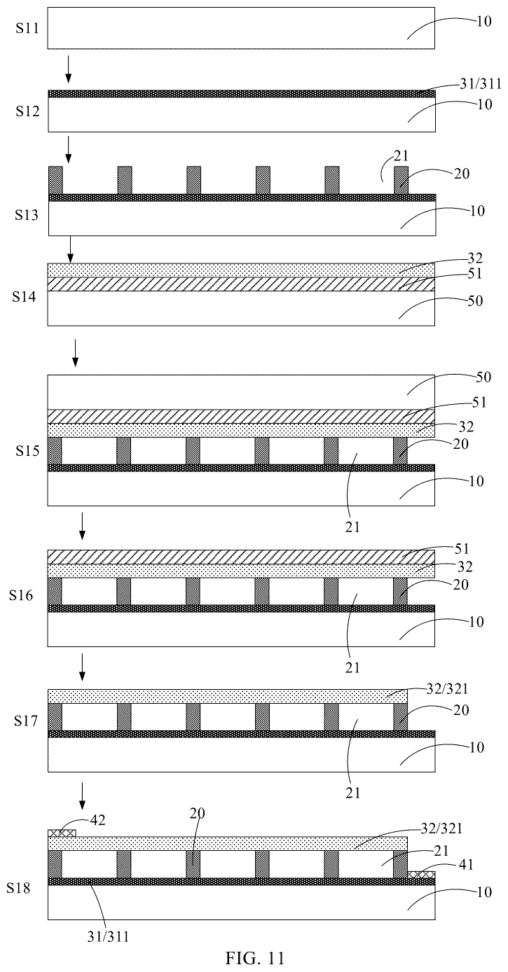

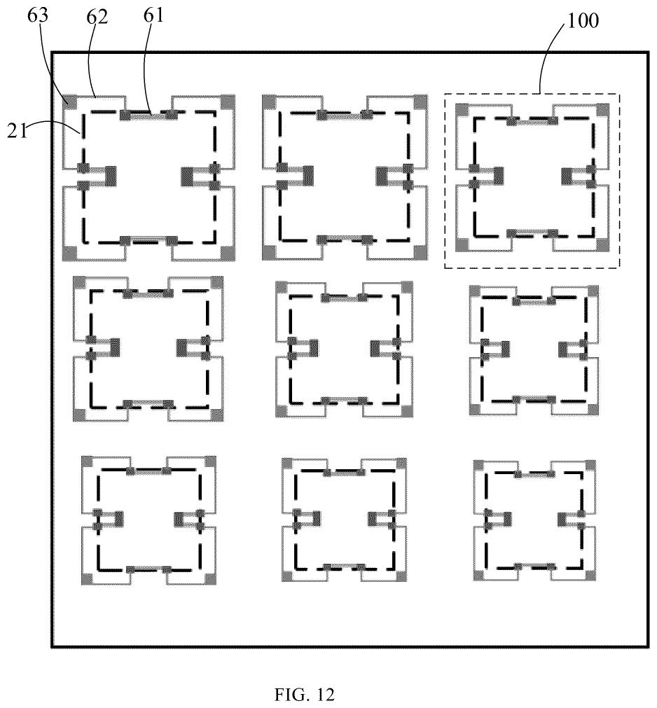

FIG. 11 is a flowchart illustrating a method for manufacturing a capacitive pressure sensor including the sensing units 100 having square films with equally proportionally varying areas. As shown in FIG. 11, the method for manufacturing a capacitive pressure sensor according to an embodiment of the present disclosure may include the following steps S11 to S16.

Step S11 includes providing a silicon substrate, and performing ion implantation on the silicon substrate to form the first pole plates 311 of the sensing units 100, wherein the first pole plates 311 are connected together to form a one-piece structure, i.e., to form the first pressure sensing layer 31.

In some examples, in the case where the silicon substrate is a P-type silicon substrate, step S11 may include: injecting phosphorus ions into the P-type silicon substrate, annealing at the high temperature of 1,100° C. to form an N well, injecting boron ions into a surface of the P-type silicon substrate with a high concentration, and performing rapid thermal annealing to form a P+ layer, thereby completing the formation of the first pole plate 311.

In the case where the silicon substrate is an N-type silicon substrate, step S11 may include: injecting boron ions into the N-type silicon substrate, annealing at the high temperature of 1,100° C. to form a P well, injecting phosphorus ions into a surface of the N-type silicon substrate with a high concentration, and performing rapid thermal annealing to form an N+ layer.

Step S12 includes forming a support layer 20 on the silicon substrate where the above steps are completed, wherein the support layer 20 has the pressure sensing chambers 21 in one-to-one correspondence with the first pole plates 311.

In some examples, a material of the support layer 20 may be silicon oxide with a thickness of 100 nm to 5 μm, and for example, the thickness of silicon oxide is 400 nm. In the case where the support layer 20 is made of silicon oxide, step S12 may include: depositing a layer of silicon oxide on the first pole plate 311 by Plasma Enhanced Chemical Vapor Deposition (PECVD), and using photoresist as a mask to perform photoetching on the layer of silicon oxide so as to expose portions of the first pole plate 311 that are arranged in a desired array, thereby forming the pressure sensing chambers 21.

Step S13 includes providing a Silicon-on-Insulator (SOI) sheet, which includes an auxiliary substrate 50, a transition layer 51 arranged on the auxiliary substrate 50, and a monocrystalline silicon layer 52 arranged on a side of the transition layer 51 distal to the auxiliary substrate 50, wherein the monocrystalline silicon layer 52 serves as the second pressure sensing layer 32. A material of the transition layer 51 may be silicon oxide.

Step S14 includes bonding the SOI sheet and the support layer 20 together through low-temperature silicon-to-silicon bonding.

Step S15 includes removing the auxiliary substrate 50 of the SOI sheet by polishing and thinning, and removing the transition layer 51 made of silicon oxide by hydrofluoric acid, such that only the monocrystalline silicon layer 52 remains, thereby forming the second pressure sensing layer 32 including the plurality of second pole plates 321.

Step S16 includes forming a first connection component 41 electrically connected to the first pressure sensing layer 31 and a second connection component 42 electrically connected to the second pressure sensing layer 32.

In some examples, step S16 includes: exposing a region required by a first electrode through photoresist-uniformizing photoetching such that the remaining region is protected by photoresist, and a portion of each of the second pressure sensing layer 32 and the support layer 20 in the region exposed by the photoresist is etched completely by using a dry etching process to expose part of the first pressure sensing layer 31.

Then, a Ti/Al metal layer, which is continuous, is sputtered by using metal sputtering, wherein the Ti layer is an adhesion layer for improving the adhesion, and has a thickness of 50 nm to 100 nm; the Al layer is a low-resistance electrode layer, and has a thickness of 300 nm to 1 μm. Finally, the first connection component 41 and the second connection component 42 to be formed are protected by using photoresist-uniformizing photoetching so as to expose other regions without photoresist protection, and finally, the Ti/Al metal layer is etched by a dry etching process and the photoresist is removed, thereby forming the first connection component 41 and the second connection component 42.

In this way, the capacitive pressure sensor is manufactured.

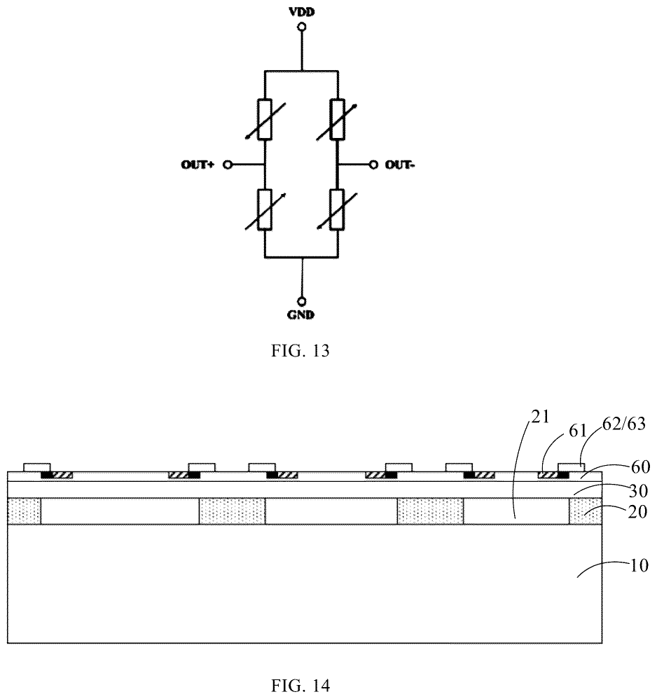

In a second example, FIG. 12 is a top view illustrating a piezoresistive pressure sensor including sensing units 100 arranged in an array and having square films with equally proportionally varying areas, FIG. 13 is a circuit diagram illustrating a Wheatstone bridge, and FIG. 14 is a cross-sectional view illustrating a piezoresistive pressure sensor including sensing units 100 having square films with equally proportionally varying areas. As shown in FIGS. 12 to 14, the pressure sensor is a piezoresistive pressure sensor, which includes a base substrate, and a support layer 20 disposed on the base substrate 10, and a plurality of pressure sensing chambers 21 are formed in the support layer 20. A pressure sensing layer is formed on a side of the support layer 20 distal to the base substrate 10. A plurality of Wheatstone bridges are formed on the pressure sensing layer to correspond to the pressure sensing chambers 21, respectively, and each Wheatstone bridge includes four pressure sensing resistors 61 connected in series. One of the pressure sensing chambers 21 and the Wheatstone bridge which is disposed on the pressure sensing layer and corresponds to a position of the one pressure sensing chamber 21 form a sensing unit 100. Orthogonal projections of the pressure sensing chambers 21 of at least two of sensing units 100 on the base substrate 10 have different areas. In this example, a thickness of the pressure sensing layers is uniform (i.e., constant), sizes of the pressure sensing chambers 21 being different determines that sizes of the effective sensing layers thereof are different, and measuring ranges and linearities adapted to the piezoresistive sensing units 100 are different, thereby forming a pressure sensor having multiple measuring ranges, which meets the high-precision measuring requirements of different measuring ranges.

In some examples, the pressure sensing resistors 61 may be obtained by performing ion implantation on the pressure sensing layer. For example, the pressure sensing layer is a P-type monocrystalline silicon layer, and N-type implantation is performed on the whole P-type monocrystalline silicon pressure sensing layer to modify the whole P-type monocrystalline silicon pressure sensing layer; P-type implantation is performed on sub-regions thereof to form the pressure sensing resistors 61, such that the pressure sensing resistors 61 are located at the inner edges of the respective pressure sensing chambers 21; P+implantation is performed on the pressure sensing resistors 61 in the sub-regions to form ohmic contact areas of the pressure sensing resistors 61, such that the pressure sensing resistors 61 can be connected together to form a Wheatstone bridge through conductive wires 62.

Further, the conductive wires 62 and connection pads 63 are formed on a side of the pressure sensing layer distal to the base substrate, and the conductive wires 62 are electrically connected to the ohmic contact areas of the pressure sensing resistors 61 to form Wheatstone bridges. The four pressure sensing resistors 61 in each Wheatstone bridge are referred to as a first pressure sensing resistor R1, a second pressure sensing resistor R2, a third pressure sensing resistor R3, and a fourth pressure sensing resistor R4, respectively. The connection pads 63 include a first connection pad VDD, a second connection pad GND, a third connection pad OUT+, and a fourth connection pad OUT−. A first terminal of the first pressure sensing resistor R1 and a first terminal of the second pressure sensing resistor R2 are electrically connected to the first connection pad VDD, a second terminal of the first pressure sensing resistor R1 and a first terminal of the third pressure sensing resistor R3 are electrically connected to the third connection pad OUT+, a second terminal of the third pressure sensing resistor R3 and a second terminal of the fourth pressure sensing resistor R4 are connected to the second connection pad GND, and a second terminal of the second pressure sensing resistor R2 and a first terminal of the fourth pressure sensing resistor R4 are connected to the fourth connection pad OUT−. The conductive wires 62 and the connection pads 63 are made of a metal.

In some examples, the sensing units 100 are arranged in an array; the areas of the orthogonal projections of the pressure sensing chambers 21 of the sensing units 100 in a same row on the base substrate 10 are equal to each other, and the areas of the orthogonal projections of the pressure sensing chambers 21 of the sensing units 100 in a same column on the base substrate 10 are monotonously increased or monotonously decreased, i.e., the areas of the pressure sensing layers of the sensing units 100 in a same column are different from each other. For example, the areas of the orthogonal projections of the pressure sensing chambers 21 (or portions of the pressure sensing layer) of the sensing units 100 in a same column on the base substrate 10 are changed in equal proportions or in equal differences. The thickness of the pressure sensing layers is uniform (i.e., constant), the sizes of the pressure sensing chambers 21 being different determines that the sizes of the effective sensing layers thereof are different, and the measuring ranges and the linearities adapted to the piezoresistive sensing units 100 are different, thereby forming a pressure sensor having multiple measuring ranges, which meets the high-precision measuring requirements of different measuring ranges.

To make the structure of the piezoresistive pressure sensor clearer, the structure of the piezoresistive pressure sensor is further described below in conjunction with a method for manufacturing the pressure sensor.

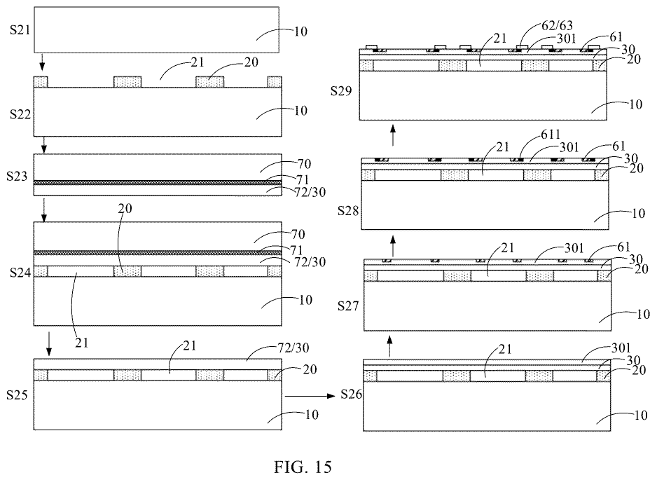

FIG. 15 is a flowchart illustrating a method for manufacturing a piezoresistive pressure sensor including sensing units 100 having square films with equally proportionally varying areas. As shown in FIG. 15, the method for manufacturing the piezoresistive pressure sensor according to an embodiment of the present disclosure includes the following steps S21 to S29.

Step S21 includes providing a base substrate 10.

In some examples, the base substrate 10 may be a silicon substrate.

Step S22 includes forming a support layer 20 on the base substrate 10, wherein the support layer 20 has a plurality of pressure sensing chambers 21 therein.

Step S23 includes providing an SOI sheet, wherein the SOI sheet includes an auxiliary substrate 70, a transition layer 71, and a monocrystalline silicon layer 72 arranged on a side of the transition layer 71 distal to the auxiliary substrate. The transition layer 72 is made of silicon oxide.

Step S24 includes bonding the monocrystalline silicon layer 72 of the SOI sheet and the support layer 20 together through low-temperature silicon-to-silicon bonding. Step S25 includes removing the auxiliary substrate 70 by grinding and thinning, and removing the transition layer 71 made of silicon oxide by hydrofluoric acid, such that only the monocrystalline silicon layer 72 remains, thereby forming the pressure sensing layer 30.

Step S26 includes making the pressure sensing layer 30 of P-type monocrystalline silicon, and performing N implantation on an entire surface of the pressure sensing layer made of P-type monocrystalline silicon to modify the pressure sensing layer made of P-type monocrystalline silicon, thereby forming a modified monocrystalline silicon pressure sensing layer 301.

Step S27 includes performing P-implantation on sub-regions thereof to form the pressure sensing resistors 61, such that the pressure sensing resistors are positioned at edges of the respective pressure sensing chambers 21.

Step S28 includes performing P+implantation on the pressure sensing resistors 61 in the sub-regions to form ohmic contact areas 611 of the pressure sensing resistors 61, so as to connect the pressure sensing resistors 61 together through the conductive wires 62 to form Wheatstone bridges.

Step S29 includes forming the conductive wires 62 and the connection pads 63.

In some examples, the four pressure sensing resistors 61 in each Wheatstone bridge are referred to as a first pressure sensing resistor 61, a second pressure sensing resistor 61, a third pressure sensing resistor 61, and a fourth pressure sensing resistor 61. The connection pads 63 include a first connection pad 63, a second connection pad 63, a third connection pad 63, and a fourth connection pad 63. A first terminal of the first pressure sensing resistor 61 and a first terminal of the second pressure sensing resistor 61 are electrically connected to the first connection pad 63, a second terminal of the first pressure sensing resistor 61 and a first terminal of the third pressure sensing resistor 61 are electrically connected to the third connection pad 63, a second terminal of the third pressure sensing resistor 61 and a second terminal of the fourth pressure sensing resistor 61 are connected to the second connection pad 63, and a second terminal of the second pressure sensing resistor 61 and a first terminal of the fourth pressure sensing resistor 61 are connected to the fourth connection pad 63. Each of the conductive wires 62 and the connection pads 63 is made of a metal. Step S25 may include depositing a metal layer on a side of the pressure sensing layer distal to the base substrate 10, and then applying photoresist, exposing, developing, and etching to form the conductive wires 62 and the connection pads 63.

In this way, the piezoresistive pressure sensor is manufactured.

An embodiment of the present disclosure provides an electronic device, which may include the pressure sensor according to any one of the foregoing embodiments.

It will be understood that the foregoing embodiments are merely exemplary embodiments adopted to illustrate the principles of the present disclosure, and the present disclosure is not limited thereto. It will be apparent to one of ordinary skill in the art that various modifications and improvements may be made therein without departing from the spirit and scope of the present disclosure, and such modifications and improvements are also considered to be within the scope of the present disclosure.

1. A pressure sensor, comprising a base substrate, and a plurality of sensing units on the base substrate, wherein each of the plurality of sensing units comprises a pressure sensing chamber, and orthogonal projections of at least two of pressure sensing chambers on the base substrate have areas different from each other.

2. The pressure sensor according to claim 1, further comprising a first pressure sensing layer and a second pressure sensing layer, wherein the first pressure sensing layer and the second pressure sensing layer are arranged on two sides of each pressure sensing chamber in a depth direction of the pressure sensing chamber, the first pressure sensing layer comprises first pole plates of respective sensing units, and the second pressure sensing layer comprises second pole plates of the respective sensing units.

3. The pressure sensor according to claim 2, wherein the base substrate comprises a silicon substrate, and the first pole plates are obtained by performing ion implantation on the silicon substrate.

4. The pressure sensor according to claim 2, wherein a material of the second pressure sensing layer is monocrystalline silicon.

5. The pressure sensor according to claim 2, further comprising a first connection component electrically connected to the first pressure sensing layer and a second connection component electrically connected to the second pressure sensing layer.

6. The pressure sensor according to claim 5, wherein the first connection component is located on a side of the first pressure sensing layer proximal to the second pressure sensing layer, and the second connection component is located on a side of the second pressure sensing layer distal to the first pressure sensing layer.

7. The pressure sensor according to claim 1, wherein each pressure sensing chamber is on the base substrate, the pressure sensor further comprises a pressure sensing layer on a side of each pressure sensing chamber distal to the base substrate, each sensing unit comprises four pressure sensing resistors which are formed on the pressure sensing layer and connected in series, and the four pressure sensing resistors form a Wheatstone bridge.

8. The pressure sensor according to claim 7, wherein the pressure sensing resistors in each sensing unit are obtained by performing ion implantation on the pressure sensing layer.

9. The pressure sensor according to claim 7, wherein each sensing unit further comprises conductive wires connecting the pressure sensing resistors together in series, and the conductive wires are located on a side of the pressure sensing layer distal to the base substrate.

10. The pressure sensor according to claim 7, wherein the base substrate is a silicon substrate.

11. The pressure sensor according to claim 1, wherein the plurality of sensing units are arranged in an array, the areas of the orthogonal projections of the pressure sensing chambers of the sensing units in a same row on the base substrate are monotonously increased or monotonously decreased, and/or the areas of the orthogonal projections of the pressure sensing chambers of the sensing units in a same column on the base substrate are monotonously increased or monotonously decreased.

12. The pressure sensor according to claim 11, wherein in a case where the areas of the orthogonal projections of the pressure sensing chambers of the sensing units in a same row on the base substrate are monotonously increased or monotonously decreased, the areas of the orthogonal projections of the pressure sensing chambers of the sensing units in the same row on the base substrate are changed in equal proportions or in equal differences; and
in a case where the areas of the orthogonal projections of the pressure sensing chambers of the sensing units in a same column on the base substrate are monotonously increased or monotonously decreased, the areas of the orthogonal projections of the pressure sensing chambers of the sensing units in the same column on the base substrate are changed in equal proportions or in equal differences.

13. The pressure sensor according to claim 1, wherein the orthogonal projection of each pressure sensing chamber on the base substrate has a shape of a rectangle or a circle.

14. A method for manufacturing a pressure sensor, the method comprising forming a plurality of sensing units on a base substrate, wherein the forming a plurality of sensing units comprises forming respective pressure sensing chambers, and orthogonal projections of at least two of the pressure sensing chambers on the base substrate have areas different from each other.

15. The method according to claim 14, wherein the forming respective pressure sensing chambers comprises forming a support layer on the base substrate, and patterning the support layer to form the respective pressure sensing chambers.

16. The method according to claim 14, further comprising forming a first pressure sensing layer and a second pressure sensing layer on two sides of each pressure sensing chamber in a depth direction of the pressure sensing chamber, wherein the first pressure sensing layer comprises first pole plates disposed in one-to-one correspondence with the pressure sensing chambers, and the second pressure sensing layer comprises second pole plates disposed in one-to-one correspondence with the pressure sensing chambers; and
wherein the base substrate is a silicon substrate, and the first pressure sensing layer is formed by performing ion implantation on the silicon substrate;
or
the forming a second pressure sensing layer on the pressure sensing chambers comprises: providing an SOI sheet, wherein the SOI sheet comprises an auxiliary substrate, and a transition layer and a monocrystalline silicon layer which are arranged on the auxiliary substrate; bonding the monocrystalline silicon layer of the SOI sheet with the base substrate provided with the pressure sensing chambers; and removing the auxiliary substrate and the transition layer to remain the monocrystalline silicon layer, thereby forming the second pressure sensing layer.

17-18. (canceled)

19. The method according to claim 14, further comprising forming a pressure sensing layer on a side of each pressure sensing chamber distal to the base substrate, and performing ion implantation on the pressure sensing layer to form a Wheatstone bridge for each sensing unit, wherein the Wheatstone bridge comprises four pressure sensing resistors connected in series; and
the method further comprises forming conductive wires on a side of the pressure sensing layer distal to the base substrate, wherein the conductive wires in each sensing unit connect the pressure sensing resistors in the sensing unit in series.

20. (canceled)

21. The method according to claim 14, wherein the plurality of sensing units are arranged in an array, the areas of the orthogonal projections of the pressure sensing chambers of the sensing units in a same row on the base substrate are equal to each other, monotonously increased or monotonously decreased, and/or the areas of the orthogonal projections of the pressure sensing chambers of the sensing units in a same column on the base substrate are monotonously increased or monotonously decreased; and
wherein in a case where the areas of the orthogonal projections of the pressure sensing chambers of the sensing units in a same row on the base substrate are monotonously increased or monotonously decreased, the areas of the orthogonal projections of the pressure sensing chambers of the sensing units in the same row on the base substrate are changed in equal proportions or in equal differences; and in a case where the areas of the orthogonal projections of the pressure sensing chambers of the sensing units in a same column on the base substrate are monotonously increased or monotonously decreased, the areas of the orthogonal projections of the pressure sensing chambers of the sensing units in the same column on the base substrate are changed in equal proportions or in equal differences.

22. (canceled)

23. The method according to claim 14, wherein the orthogonal projection of each pressure sensing chamber on the base substrate has a shape of a rectangle or a circle.

24. An electronic device, comprising the pressure sensor according to claim 1.
